(19) United States
(12) Patent Application Publication
(10) Pub. No.: US 2019/0279313 A1
(43) Pub. Date: Sep. 12, 2019

(54) POWER EXCHANGE MANAGEMENT DEVICE, POWER EXCHANGE MANAGEMENT METHOD, AND POWER EXCHANGE MANAGEMENT PROGRAM

(71) Applicant: Hitachi, Ltd., Tokyo (JP)

(72) Inventors: Asako MIYAMOTO, Tokyo (JP); Soichi FURUYA, Tokyo (JP); Hiroki SATOH, Tokyo (JP); Takuya AKASHI, Tokyo (JP); Ying ZHONG, Tokyo (JP); Naofumi TOMITA, Tokyo (JP)

(21) Appl. No.: 16/335,279

(22) PCT Filed: Oct. 26, 2016
(86) PCT No.: PCT/JP2016/081772

§ 371 Date: Mar. 21, 2019

(51) Int. Cl. G06Q 50/06; G06Q 30/02; G05F 1/66; G01R 21/133

(52) U.S. Cl. CPC G06Q 50/06; G01R 21/1333; G05F 1/66; G06Q 30/0208

(57) ABSTRACT

A power exchange management device includes: a power consumer service processor that receives bid solicitation information from a power consumer, the bid solicitation information being for soliciting exchange of power; a prosumer service processor that publicizes a bid solicitation condition on a terminal device of a prosumer on the basis of the bid solicitation information and receives application information responding to the bid solicitation information from the terminal device of the prosumer; a prosumer power transmission information acquirer that acquires information about an amount of power transmitted to the grid by the power transmission facility of the prosumer by reverse power flow; and a target manager (24) that compares the acquired amount of transmitted power with a target value set on the basis of the bid solicitation information and the application information and determines an incentive to be offered to the prosumer depending on a result of the comparison.

### TECHNICAL FIELD

The present invention relates to a power exchange management device, a power exchange management method, and a power exchange management program.

### BACKGROUND ART

Electricity liberalization has been advanced in recent years, and power consumers ranging from large-scale commercial facilities to general households can buy power from entities other than the conventional electric power companies. In addition, general households equipped with battery facilities, solar photovoltaic power generation facilities and cogeneration systems can be regarded as sellers of power. This trend is expected to become stronger as battery facilities, solar photovoltaic power generation facilities and other facilities can be purchased and operated more economically and are thus used more widely, and as the spread of electric vehicles and fuel-cell vehicles each having a battery in their inside is accelerated.

Nowadays, a feed-in tariff is used as a scheme through which consumers, such as general households, having power supplying capabilities sell surplus power. In this scheme, general entities which purchase surplus power are, for example, electric power companies and the like. However, there is no guarantee that the use of the current scheme will continue permanently in any regions in future. Even at present, many countries and regions have already revised purchasing prices to lower prices. Against this background, attention is paid to “local production for local consumption” of power. According to this policy, surplus power is not sold at wholesale prices in trading markets or the like, but is sold at prices equivalent to retail prices for other consumers. Accordingly, higher compensation can be expected from this selling. The power exchange through the “local production for local consumption” scheme means that an entity possessing a power generation facility in a local area supplies (sells) power generated in the local area to another entity in the local area for exchange. Unlike the conventional power supply system in which locations of power generation are distant from locations of power consumption, the power exchange through the “local production for local consumption” scheme enables power produced by low-carbon-emitting distributed power sources to be consumed in a relatively near place, increases the spread of distributed power sources, and contributes to a reduction in carbon emission in the society. Moreover, the distributed power sources are easier to install in a shorter time than the conventional large-scale power generation facilities, and consequently make contributions to revitalizing the local economy of a region or the like.

Patent Literature 1 discloses an example of a power exchange method other than the feed-in tariff scheme. According to the intermediation of power using a power supply/demand intermediation system disclosed in Patent Literature 1, power suppliers propose their desired sales unit prices (propose their power supply conditions) like 12 yen/kWh or more and 5 yen/kWh or more. Meanwhile, power consumers (schools, supermarkets, factories and the like) propose their desired purchasing unit prices (propose their power demand information) like no compensation (0 yen)/kWh, 10 yen/kWh or less and 8 yen/kWh or less. The power supply/demand intermediation system compares the power demand information with the power supply conditions to match the power consumers with the power suppliers. In other words, the intermediation (supplying power for exchange) disclosed in Patent Literature 1 presumes that compensation is determined such that “the power supplier 20 wishing to sell power at higher prices may propose a higher price as a power supply condition” (paragraph 0023 in Patent Literature 1). Incidentally, the power exchange (supply) is performed through a charged battery apparatus transported from the power supplier to the power consumer like a school, a supermarket or a factory and connected to a power receiving apparatus of the power consumer.

### CITATION LIST

### Patent Literature

Patent Literature 1: Japanese Patent Application Publication No. 2014-187796

### SUMMARY OF INVENTION

### Technical Problem

Although the incentive for the power exchange using money (or compensation (AA yen/kWh)) disclosed in Patent Literature 1 is attractive in the short run, but may not be effective in the long run because the motivation of supplying power becomes gradually weaker. Hence, a more effective incentive is eagerly awaited.

In Patent Literature 1, the power supplier can have sufficient monetary motivation for supplying surplus power. The motivation, however, becomes gradually weaker in the long run. Therefore, it is difficult to continuously motivate the power supplier to supply power repeatedly in the future as well. In addition, according to Patent Literature 1, the compensation is limited to money. If products from a local area can be used as the compensation for power, power suppliers in the same local area can be strongly motivated. Patent Literature 1, however, pays no consideration to this point.

From the above viewpoint, an object of the present invention is to realize power exchange while continuously providing an incentive for the power exchange for a long time.

### Solution to Problem

A power exchange management device according to the present invention includes: a power consumer service processor that receives bid solicitation information from a terminal device of a power consumer, the bid solicitation information being for soliciting exchange of power, the power consumer having a battery facility capable of storing power from a grid, the power consumer using the power stored in the battery facility to produce products or provide services; a prosumer service processor that publicizes a bid solicitation condition on a terminal device of a prosumer on the basis of the bid solicitation information and receives application information responding to the bid solicitation information from the terminal device of the prosumer, wherein the prosumer has (i) an in-house power generation facility and (ii) a power transmission facility capable of providing power to the grid by reverse power flow, and is thereby capable of transmitting power to the grid; a prosumer power transmission information acquirer that acquires information about an amount of power transmitted to the grid by the power transmission facility of the prosumer by reverse power flow; and a target manager that compares the acquired amount of transmitted power with a target value of an amount of power to be exchanged from the prosumer to the power consumer and determines an incentive to be offered to the prosumer depending on a result of the comparison, wherein the target value is set on the basis of the bid solicitation information and the application information. Other means will be described in an embodiment of the present invention.

### Advantageous Effects of Invention

The present invention can realize power exchange while continuously providing an incentive for the power exchange for a long time.

### BRIEF DESCRIPTION OF DRAWINGS

FIG. 1 is a diagram for explaining an environment in which a power exchange management device is used.

FIG. 2 is a diagram for explaining a configuration of the power exchange management device.

FIG. 3 is a diagram for explaining power supply-demand information.

FIG. 4 is a diagram for explaining contract information.

FIG. 5A is a diagram for explaining cumulative exchanged power amount information, and FIG. 5B is a diagram for explaining an exchange progress graph.

FIG. 6 is a flowchart showing a part of a process procedure.

FIG. 7 is a flowchart showing a continuing part of the process procedure subsequent to that shown in FIG. 6.

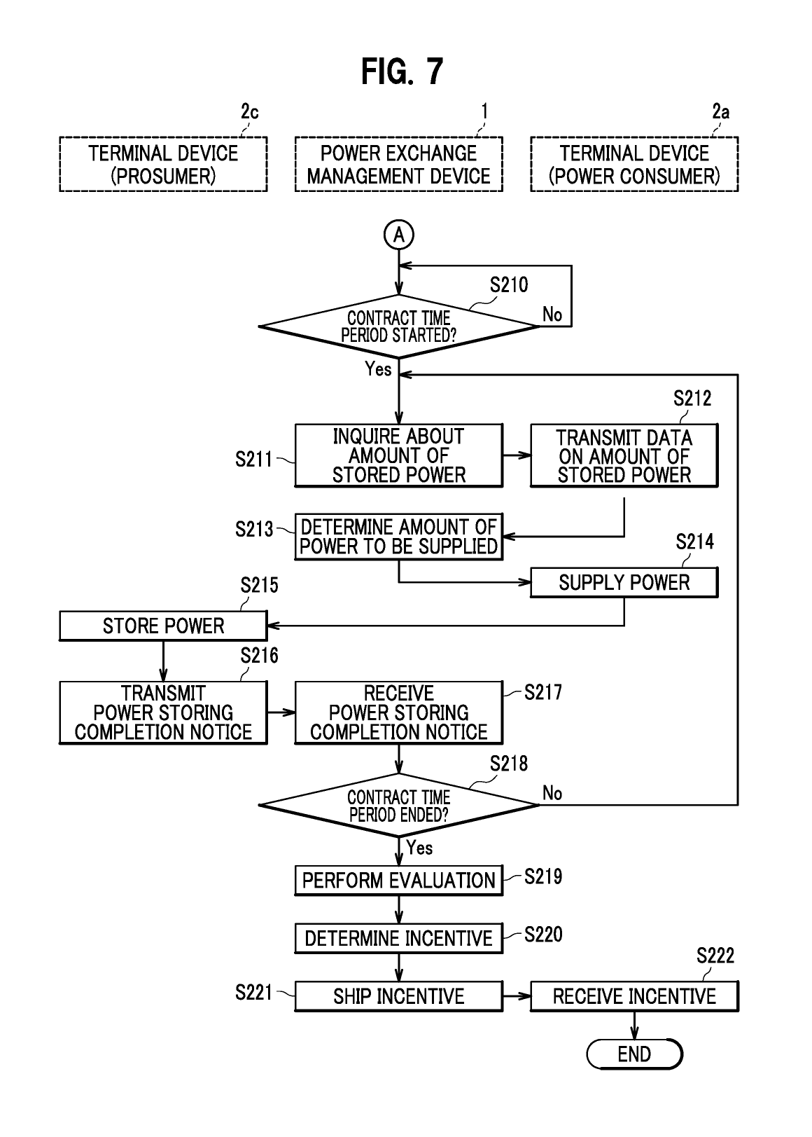

FIGS. 8A, 8B, 8C and 8D show examples of a screen display.

FIGS. 9A, 9B and 9C show other examples of the screen display.

FIGS. 10A, 10B, 10C and 10D show other examples of the screen display.

### DESCRIPTION OF EMBODIMENTS

Hereinafter, modes for carrying out the present invention (hereinafter referred to as “embodiments”) will be described in detail with reference to the accompanying drawings and the like.

(Environment in which Power Exchange Management System is to be Used)

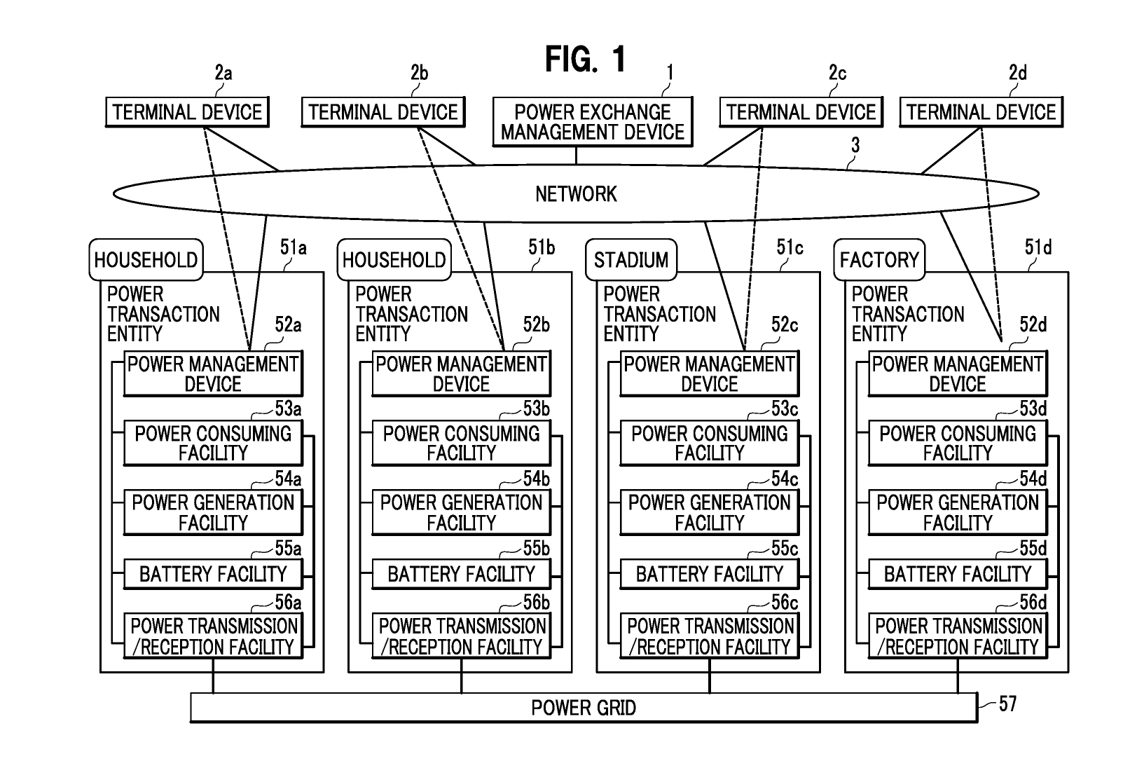

Using FIG. 1, a description will be given of an environment in which a power exchange management device 1 is to be used. In the embodiment, there are four power transaction entities 51a, 51b, 51c, 51d. The power transaction entities 51a, 51b are households. The power transaction entity 51c is a stadium. The power transaction entity 51d is a factory. Incidentally, in practice, no limit is imposed on the number of power transaction entities, or types of power transaction entities.

Each power transaction entity 51 includes a power management device 52, a power consuming facility 53, a power generation facility 54, a battery facility 55, a power transmission/reception facility 56, and a terminal device 2 (an in-home display, a smartphone or the like). In FIG. 1, the last letters a, b, c, d in the reference signs denoting the facilities and the like correspond to the last letters a, b, c, d in the reference signs denoting the power transaction entities to which the facilities and the like belong.

The power management device 52 is a general computer. The power management device 52 is connected with the power consuming facility 53, the power generation facility 54, the battery facility 55 and the power transmission/reception facility 56, as well as controls and records amounts of power flowing among the facilities 53, 54, 55, 56. The terminal device 2 is capable of communicating with the power management device 52 of the power transaction entity 51 using a short-range radio communication technology via the network 3, or not via the network 3. A user belonging to the power transaction entity 51 uses the terminal device 2. The power exchange management device 1 is also capable of communicating with each terminal device 2 and each power management device 52 via the network 3. Incidentally, the power transmission/reception facility 56 is capable of not only receiving power from a power grid 57, but also transmitting surplus power to the power grid 57 by reverse power flow, where the surplus power is a more amount of power generated by the power generation facility 54 than the power transaction entity consumes. Incidentally, In FIG. 1, thick solid lines each represent a flow of power, while thin solid and dashed lines each represent a flow of information.

Examples of the power consuming facilities 53a, 53b in the power transaction entities 51a, 51b are home electrical equipment like a refrigerator and a water heater. Examples of the power consuming facility 53c in the power transaction entity 51c are an air conditioning facility, an electrical illumination facility, and a stage facility. An example of the power consuming facility 53d in the power transaction entity 51d is a food production facility in a case where the power transaction entity 51d is a food product manufacturer. The power generation facilities 54a, 54b in the power transaction entities 51a, 51b are, for example, an in-house solar photovoltaic power generation facility. Examples of power generation facilities 54c, 54d in the power transaction entities 51c, 51d include a cogeneration system, and an in-house diesel engine power generation facility.

The battery facility 55 in each power transaction entity 51 is an arbitrary type of battery facility which stores power generated by the power generation facility 54 or commercial power received by the power transmission/reception facility 56 from the power grid 57. The capacities of the battery facilities 55c, 55d are each far greater than those of the battery facilities 55a, 55b.

As clear from the above descriptions, the power consuming facilities, the power generation facilities, the battery facilities and the like are substantially common among the power transaction entities 51 except that the types and capacities of the power consuming facilities, the power generation facilities, and the battery facilities are different among the power transaction entities 51. Each power transaction entity 51 receives power from the power grid 57 or causes the power generation facility 54 to generate power, in order for the power consuming facility 53 to consume needed power, while storing surplus power in the battery facility 55.

In general, timings at which a surplus of power or a shortage of power occurs vary from one power transaction entity to another. In other words, each power transaction entity 51 becomes an entity (prosumer) which supplies surplus power at some times, and becomes an entity (power consumer) which receives power at other times. This embodiment assumes that each household is fundamentally a prosumer having a power generation facility that generates more power than the household consumes on a weekly-average basis. This embodiment further assumes that the stadium 51c and the factory 51d consume more power than their power generation facilities generate, and need to receive additional power from an electric power company or prosumers. Hereinbelow, a description will be given of an example where the power transaction entities 51a, 51b are prosumers while the power transaction entities 51c, 51d are power consumers.

In FIG. 1, each prosumer supplies its designated amount of power to the power grid 57 for the time length designated for exchange. Meanwhile, each power consumer consumes the amount of power designated for exchange from the power grid 57 in accordance with the time period and the amount of power designated for exchange beforehand.

### (Power Consumption Pattern of Power Consumers)

The power consumer 51c is a stadium. The power demand of the stadium is concentrated for a specific time period (hours) during which the power consumer 51c holds an event. For example, in a case where the power consumer 51c plans to hold a “year-end idol concert” between 22:00 and 24:00 on Dec. 31, 2016, enormous power demand is concentrated during the two hours because the power consumer 51c puts the air conditioning facility, electrical illumination facility, stage facility and the like into operation. The power demanded while the stadium is closed is far smaller than during the two hours.

With this taken into account, while the power consumer 51c is closed in the preparation time period preceding Dec. 31, 2016, the power consumer 51c receives the amount of power assigned for exchange from multiple prosumers (like individual idol supporters) in multiple steps, and stores the received power in the battery facility 55c. Then, the power consumer 51c consumes the stored power in the time period between 22:00 and 24:00 on Dec. 31, 2016. This method of using the battery facility 55c will be referred to as a “time-to-time storage one-time consumption pattern”.

The power consumer 51d is a factory, and needs power substantially evenly during a particular time period in order to keep the operating rate of production lines at a constant level. For example, in a case where the power consumption 51d puts a production line for “cheese from CC prefecture for autumn sale 2017” into operation between Nov. 1, 2016 and Oct. 31, 2017, the substantially same amount of power demand occurs every day during this time period. For example, in a case where an amount of power which the power consumer 51d plans to consume on a particular date in this time period is 1,000 kWh, the power consumer 51d collects 500 kWh of surplus power in total from the prosumers 51a, 51b (gastronome or the like) each day in a two-day period preceding the particular date, and stores the collected amount of power. This method of using the battery facility 55d will be referred to as a “time-to-time storage time-to-time consumption pattern”.

### (Incentive)

Each power consumer gives each prosumer a compensation for the amount of power supplied from the prosumer for exchange. In many conventional practices, money has been used as the compensation. In this embodiment, however, an economic value, not money, is used as part or all of the compensation. This economic value is an “incentive” mentioned above, and is local produce of an area to which the prosumer and the power consumer belong to or virtual currencies (points) which are used in the area. Of course, products manufactured by the power consumer itself may be used as the incentive.

For example, an incentive provided by the power consumer 51c may be an “idol T-shirt” distributed for a fee in its stadium, or may be an “admission discount coupon” of an event to be held at the stadium. On the other hand, an incentive provided by the power consumer 51d may be “cheese from CC Prefecture” which is manufactured in its own factory. There are variations among amounts of power supplied by prosumers for exchange. For example, if the compensation is equivalent to several hundred yen or the like in value, in many cases, the power consumer feels that preparing both of small amounts of money and small-valued incentives as compensations at the same time is bothersome and time-consuming. In addition, prosumers may be interested in only incentives of products in many cases. In such cases, only the incentives are used for the compensation payment.

### (Evaluation of Prosumers)

Each power consumer operating a stadium or the like evaluates some prosumers highly, and others not. It is a matter of course that the power consumer highly evaluates prosumers who supply more power to the power consumer for a predetermined contract time period for exchange. Accordingly, the larger the contracted amount of power to be supplied to the power consumer for exchange, the higher the value of the incentive given to the prosumer by the power consumer. In a case, however, where the prosumer is found to fail to supply the amount of power contracted for exchange at the contract end time, the power consumer lowers the value of the incentive given to the prosumer.

### (Control of Amount of Power to be Exchanged)

The most important matter to a power consumer is that each prosumer securely completes supplying all the contracted amount of power by the contract end time. With this taken into account, the present embodiment assumes that a prosumer supplies the contracted amount of power for exchange in multiple steps in the contract time period. Each time a prosumer supplies part of the contracted total amount of power for exchange, the power exchange management device informs the prosumer of a remaining amount of power which the prosumer has to supply by the contract end time in order to have the prosumer complete supplying all the contracted amount of power by the contract end time. With such guidance, the power exchange management device controls the amount of power to be actually supplied by the prosumer for exchange (discussed later in detail).

### (Power Exchange Management System)

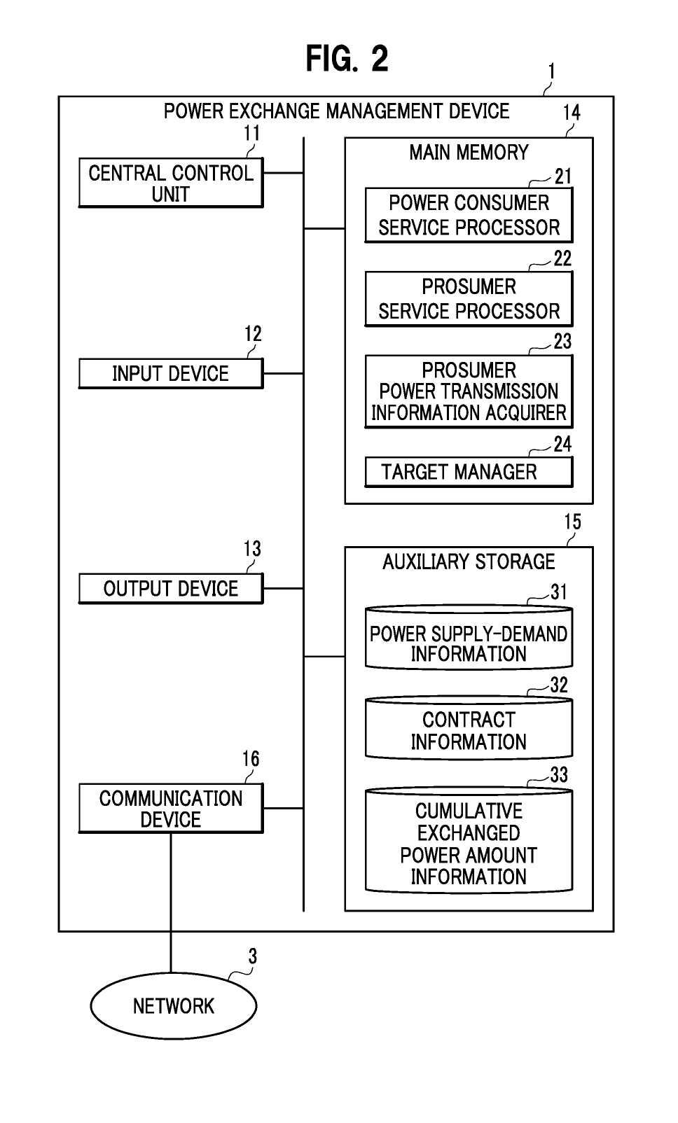

Using FIG. 2, a description will be given of a configuration of the power exchange management device 1. The power exchange management device 1 is a general computer. The power exchange management device 1 includes a central control (central processing) unit 11, an input device 12, an output device 13, a main memory device 14, an auxiliary storage 15, and a communication device 16. These units are connected together via a bus. The auxiliary storage 15 stores power supply-demand information 31, contract information 32, and cumulative exchanged power amount information 33. A power consumer service processor 21, a prosumer service processor 22, a prosumer power transmission information acquirer 23, and a target manager 24 included in the main memory device 14 are realized as computer programs. In the following descriptions, an “-er(-or)” specified as an actor performing a function means that the -er(or) is executed by the central control unit 11 via the main memory device 14.

### (Power Supply-Demand Information)

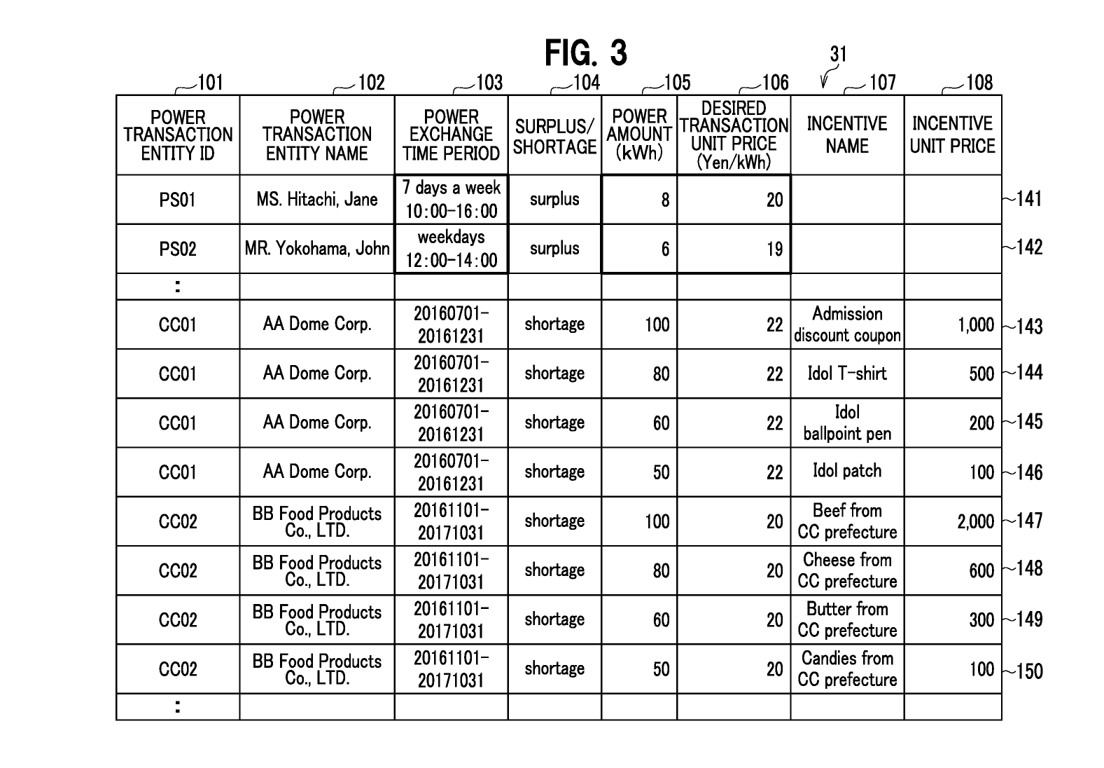

Using FIG. 3, a description will be given of the power supply-demand information 31. The power supply-demand information 31 can be said to be prediction of power demand in the future (or power supplied when the amount of power generation exceeds the amount of the power demanded). Each piece of the power supply-demand information 31 is associated with a power transaction entity ID stored in a power transaction entity ID column 101, and includes: a power transaction entity name column 102 storing a power transaction entity name; a power exchange time period column 103 storing a power exchange time period; a surplus/shortage column 104 storing information indicative of a surplus or a shortage; a power amount column 105 storing an amount of power; a desired transaction unit price column 106 storing a desired transaction unit price; an incentive name column 107 storing an incentive name; and an incentive unit price column 108 storing a unit price of the incentive.

Each power transaction entity ID in the power transaction entity ID column 101 is an identifier which uniquely identifies a power transaction entity.

Each power transaction entity name in the power transaction entity name column 102 is the personal name or the company name of a power transaction entity.

Each power exchange time period in the power exchange time period column 103 is a time period during which power surplus or shortage occurs.

Each item in the surplus/shortage column 104 is described as either “surplus” or “shortage”. A denotation of “surplus” means that a surplus of power occurs in the corresponding power transaction entity during the corresponding power exchange time period. A denotation of “shortage” means that a shortage of power occurs in the corresponding power transaction entity during the corresponding power exchange time period. A denotation of “surplus” implies that the power transaction entity of the corresponding record may become a prosumer, while an denotation of “shortage” implies that the power transaction entity of the corresponding record may become a power consumer.

Each of the power amounts described in the power amount column 105 denotes an amount of power which can be supplied by a single prosumer each day in a power exchange time period, or a total amount of power which a power consumer wishes to receive from a prosumer in the power exchange time period.

Each of the desired transaction unit prices described in the desired transaction unit price column 106 denotes a sales unit price or a purchase unit price which a power transaction entity desires.

Each of the incentive names in the incentive name column 107 denotes the name of an incentive which a power consumer pays (offers) to a prosumer as the compensation for the power. Only for records having “shortage” in the surplus/shortage column, the incentive name is stored in each record.

Each of the incentive unit prices described in the incentive unit price column 108 denotes the unit price of an incentive. Only for records having “shortage” in the surplus/shortage column, the unit price of an incentive is stored in each record.

The power supply-demand information 31 (FIG. 3) as a whole, for examples, indicates the following.

Ms. Hitachi, Jane can generate a surplus power amount of 8 kWh/day in a time period between 10:00 and 16:00 everyday, and to sell the surplus power at a price of 20 yen/kWh (record 141).

Mr. Yokohama, John can generate a surplus power amount of 6 kWh/day in a time period between 12:00 and 14:00 on weekdays, and to sell the surplus power at a price of 19 yen/kWh (record 142).

Incidentally, the power exchange management device 1 may obtain such information as the records 141, 142, by receiving registrations from the corresponding prosumers, or by storing statistical values of the past data instead of receiving the registrations (discussed later in detail).
AA Dome Corporation intends to receive a large amount of power (for example, tens of thousands of kWh) in a time period between Jul. 1, 2016 and Dec. 31, 2016. AA Dome Corporation intends to receive the total necessary amount of power from multiple prosumers by dividing the total necessary amount of power into small amounts of power and collecting all the small amounts of power from multiple prosumers. AA Dome Corporation offers four plans: a “100 kWh” plan, an “80 kWh” plan, a “60 kWh” plan and a “50 kWh” plan, to facilitate each prosumer to conclude a contract with AA Dome Corporation. The desired transaction (purchase) unit price is 22 yen/kWh for all the plans (records 143 to 146).
AA Dome Corporation prepares incentives, such as admission discount coupons (each equivalent to 1,000 yen in value), idol T-shirts (each equivalent to 500 yen in value), idol ballpoint pens (each equivalent to 200 yen in value) and idol patches (each equivalent to 100 yen in value) in descending order of the amounts of power to be received for exchange.
BB Food Products, Co., Ltd. needs a large amount of power (for example, tens of thousands of kWh) in a time period between Nov. 1, 2016 and Oct. 31, 2017 for the purpose of putting a factory into operation to manufacture food products from CC Prefecture. Like the AA Dome Corporation, BB Food Products, Co., Ltd. divides the total necessary amount of power into small amounts of power to be received from multiple prosumers for exchange in the time period, and offers four plans: a “100 kWh” plan, an “80 kWh” plan, a “60 kWh” plan and a “50 kWh” plan. The desired transaction (purchase) unit price is 20 yen/kWh for all the plans (records 147 to 150). ⋅ BB Food Products, Co., Ltd. prepares incentives, such as blocks of beef from CC Prefecture (each equivalent to 2,000 yen in value), blocks of cheese from CC Prefecture (each equivalent to 600 yen in value), blocks of butter from CC Prefecture (each equivalent to 300 yen in value), and boxes of candies from CC Prefecture (each equivalent to 100 yen in value) in descending order of the amounts of power to be received for exchange.

It is concerned that whether the operator of the power exchange management device 1 storing the power supply-demand information 31 can obtain information about the desired transaction prices (column 106). A desired transaction price is what each power transaction entity hesitates to disclose to parties who have not concluded a nondisclosure agreement with the power transaction entity yet. The power supply-demand information 31, therefore, does not have to include the desired transaction unit price column 106. Each time the power exchange management device 1 receives a membership registration or application information from a prosumer or a power consumer, the power exchange management device 1 creates a new record in the power supply-demand information 31. The power exchange management device 1 creates the power supply-demand information 31 for each region. Examples of the region include metropolis, prefectures, cities, towns and villages. The size of the region can be freely selected. FIG. 3 shows an example of the power supply-demand information 31 in “CC prefecture”.

### (Contract Information)

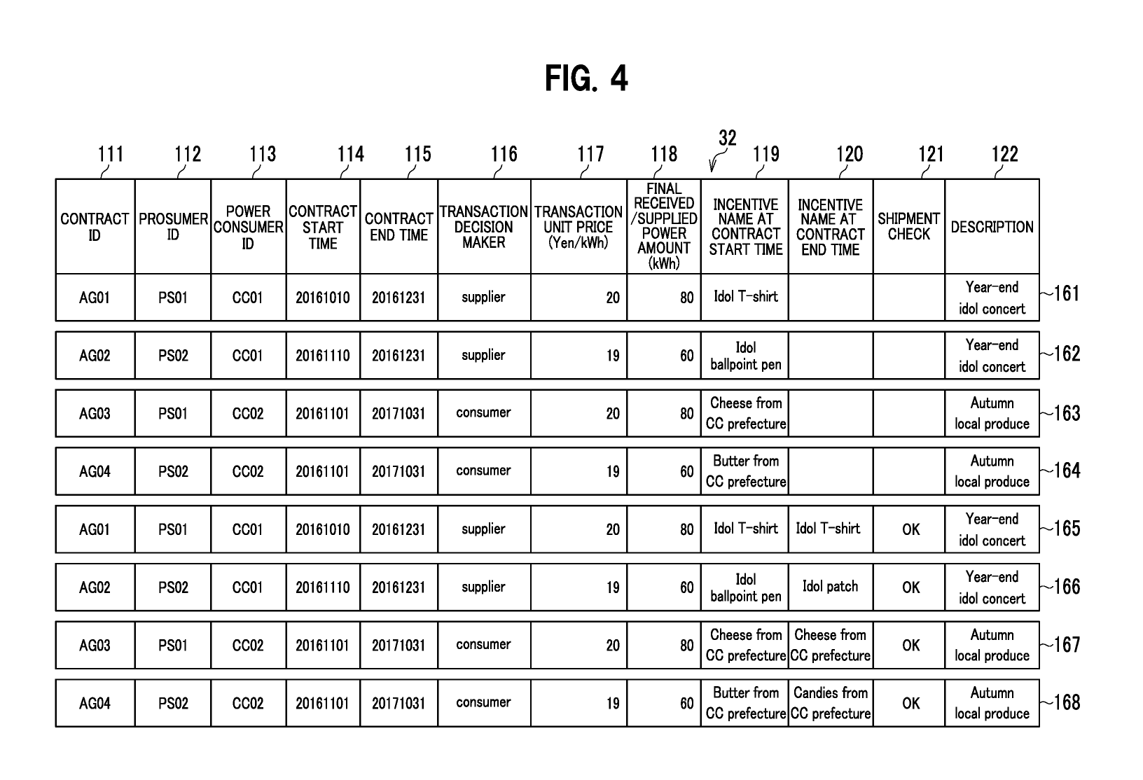

Using FIG. 4, a description will be given of the contract information 32. Each piece of the contract information 32 is associated with a contract ID stored in a contract ID column 111, and includes: a prosumer ID column 112 storing a prosumer ID; a power consumer ID column 113 storing a power consumer ID; a contract start time column 114 storing time information indicative of when the contract starts; a contract end time column 115 storing time information indicative of when the contract ends; a transaction decision maker column 116 storing information indicating the party who decides when to enter into contracts; a transaction unit price column 117 storing a transaction unit price; a final received/supplied power amount column 118 storing a final total amount of power to be received or supplied; a contract start time incentive name column 119 storing the name of a contract start time incentive; an contract end time incentive name column 120 storing the name of a contract end time incentive; a shipment check column 121 storing a shipment flag; and a description column 122 storing a description.

Each contract ID described in the contract ID column 111 is an identifier which uniquely identifies a contract. In the embodiment, the contract is concluded between a prosumer and a power consumer.

Each prosumer ID described in the prosumer ID column 112 is an identifier which uniquely identifies a power transaction entity as the prosumer involved in the contract.

Each power consumer ID described in the power consumer ID column 113 is an identifier which uniquely identifies a power transaction entity as the power consumer involved in the contract.

Each contract start time described in the contract start time column 114 indicates a date on which the contract time period starts.

Incidentally, the contract time period is part of the power exchange time period of the power consumer (included in the column 103 in FIG. 3).

Each contract end time described in the contract end time column 115 is a date on which a contract time period ends.

Each transaction decision maker in the transaction decision maker column 116 is described as either “supplier” or “consumer”. A prosumer supplies a contracted amount of power to the power consumer in steps in the contract time period. For example, the prosumer stores a surplus of the power generated by daytime solar photovoltaic power generation in the battery facility, and outputs it to the power grid 57 in the night. A denotation of “supplier” means that the prosumer can decide the timing when the prosumer supplies power for exchange. A denotation of “consumer” means that the power consumer can decide the timing when the power consumer receives power for exchange.

Each transaction unit price described in the transaction unit price column 117 is a price per unit amount of power which is agreed between the prosumer and the power consumer. Incidentally, this column is not essential for the same reason as discussed above.

Each final amount of power to be received or supplied, described in the final received/supplied power amount column 118, is a total amount of power which the prosumer promises to supply to the power consumer in the contract time period, and is one of the amounts of power under the above-mentioned plans (column 105 in the records 143 to 150 in FIG. 3).

Each contract start time incentive name described in the contract start time incentive name column 119 is the name of the incentive which the power consumer promises, at the contract start time, to offer to the prosumer under a condition that the content of the contract be followed.

Each contract end time incentive name described in the contract end time incentive name column 121 is the name of an incentive which the power consumer decides at the contract end time to offer to the prosumer on the basis of an evaluation of whether the prosumer actually has followed the contract. The contract end time incentive name is stored when the contract ends.

A denotation of shipment flag “OK” in the shipment check column 121 indicates that arrangement of shipping of the incentive to the prosumer has been completed. The shipment flag is also stored when the contract ends.

Each description stored in the description column 122 is optional information to be used as a note.

Each time a contract is concluded, the target manager 24 of the power exchange management device 1 (FIG. 2) creates a new record of the contract information 32. Thereafter, the target manager 24 obtains information from each power management device 51 (FIG. 1), and updates the value of the cumulative amount of exchanged power per power settlement unit, which is twice every hour (on 0 and 30 minutes past every hour). For simplicity of explanation, FIG. 4 shows records changing with time on a single piece of paper. For example, in reality, records 161, 165 concerning the same contract “AG01” are never displayed simultaneously. This is represented by gaps between the records.

The contract information 32 (FIG. 4) as a whole, for example, represents the following.

Regarding Records 161, 165

AA Dome Corporation (CC01) planned to hold a year-end idol concert which was scheduled to end at 24:00 on Dec. 31, 2016. On Oct. 10, 2016, AA Dome Corporation and Ms. Hitachi, Jane (PS01) concluded a contract requiring that Ms. Hitachi, Jane supply power to AA Dome Corporation in the future. In this case, the final total amount of power to be received/supplied was set at 80 kWh, and an “idol T-shirt” was tentatively selected as the incentive at the contract start time (record 161). Thereafter, although not understood directly from FIG. 4, Ms. Hitachi, Jane completed supplying a total of 80 kWh of power to AA Dome Corporation in steps (on multiple dates) for exchange in the time period ending 24:00 on Dec. 31, 2016. Thus, as contracted, Ms. Hitachi, Jane received the “idol T-shirt” which was selected at the contract start time (record 165).

Regarding Records 162, 166

AA Dome Corporation (CC01) planned to hold the year-end idol concert which was scheduled to end at 24:00 on Dec. 31, 2016. On Nov. 10, 2016, AA Dome Corporation and Mr. Yokohama, John (PS02) concluded a contract requiring that Mr. Yokohama, John supply power to AA Dome Corporation in the future. In this case, the final total amount of power to be received/supplied was set at 60 kWh, and an “idol ballpoint pen” was tentatively selected as the incentive at the contract start time (record 162). The value of the “idol ballpoint pen” is less than that of “idol T-shirt” selected for Ms. Hitachi, Jane. This was due to the fact that the contract of Mr. Yokohama, John would start later than the contract of Ms. Hitachi, Jane.

Thereafter, although not understood directly from FIG. 4, Mr. Yokohama, John actually supplied only a total of 50 kWh of power to AA Dome Corporation in steps for exchange in the time period ending 24:00 on Dec. 31, 2016 (failed to supply the final total amount of power to be received/supplied). Unlike in the case of Ms. Hitachi, Jane, AA Dome Corporation did not give a high evaluation to the amount of power which Mr. Yokohama, John actually supplied for exchange. Thus, Mr. Yokohama, John was not entitled to receive the “idol ballpoint pen” which was selected at the contract start time, and received an “idol patch” whose value was less than that of the “idol ballpoint pen” (record 166).

Regarding Records 163, 167

BB Food Products, Co., Ltd. (CC02) planned to put a production line of the company's factory into operation for the time period between Nov. 1, 2016 and Oct. 31, 2017. On Nov. 1, 2016, BB Food Products, Co., Ltd. and Ms. Hitachi, Jane (PS01) concluded a contract requiring that Ms. Hitachi, Jane (PS01) supply power to BB Food Products, Co., Ltd. in the future. In this case, the final total amount of power to be received/supplied was set at 80 kWh, and a “block of cheese from CC Prefecture” was tentatively selected as the incentive at the contract start time (record 163). Thereafter, although not understood directly from FIG. 4, Ms. Hitachi, Jane actually completed supplying a total of 80 kWh of power to BB Food Products, Co., Ltd. in steps for exchange in the time period ending Oct. 31, 2017. Thus, as contracted, Ms. Hitachi, Jane received the “block of cheese from CC Prefecture” which was selected at the contract start time (record 167).

Regarding Records 164, 168

BB Food Products, Co., Ltd. (CC02) planned to put a production line of a company's factory into operation for the time period between Nov. 1, 2016 and Oct. 31, 2017. On Nov. 1, 2016, BB Food Products, Co., Ltd. and Mr. Yokohama, John (PS02) concluded a contract requiring that Mr. Yokohama, John (PS02) supply power to BB Food Products, Co., Ltd. in the future. In this case, the final amount of power to be received/supplied was set at 60 kWh, and a “block of butter from CC Prefecture” was tentatively selected as the incentive at the contract start time (record 164).

Thereafter, although not understood directly from FIG. 4, Mr. Yokohama, John actually supplied only a total of 50 kWh of power to BB Food Products, Co., Ltd. in steps for exchange in the time period ending Oct. 31, 2017 (failed to supply the final amount of power to be received/supplied). Unlike in the case of Ms. Hitachi, Jane, BB Food Products, Co., Ltd. did not give a high evaluation to the amount of power which Mr. Yokohama, John actually supplied for exchange. Thus, Mr. Yokohama, John was not entitled to receive the “block of butter from CC prefecture” which was selected at the contract start time, and received a “box of candies from CC Prefecture” whose value was less than that of the “block of butter from CC Prefecture” (record 168).

### (Cumulative Exchanged Power Amount Information)

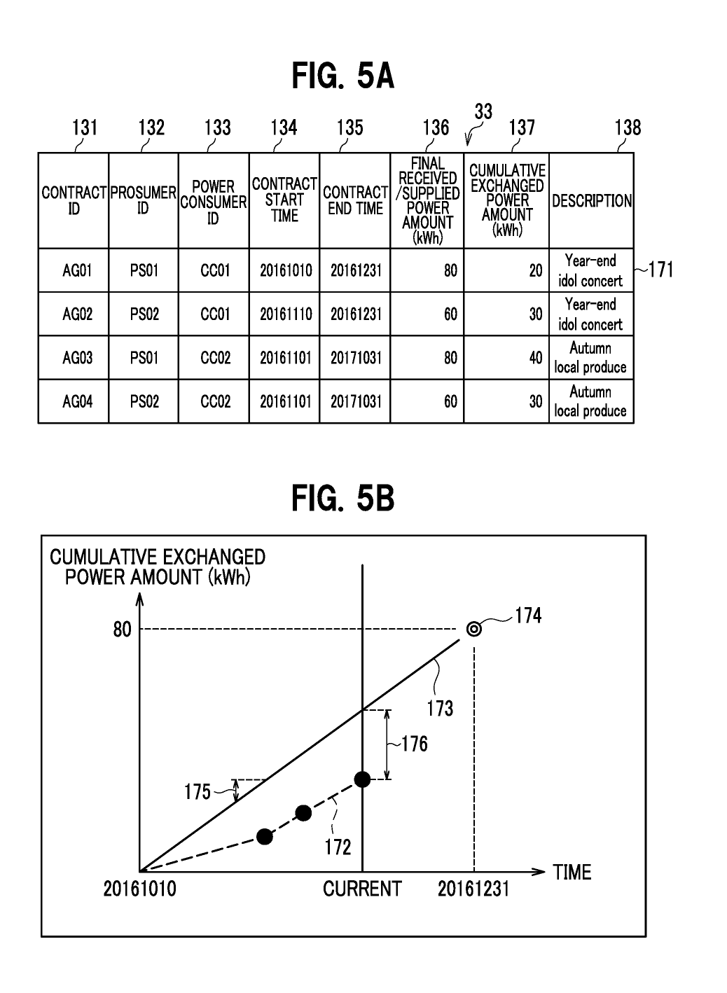

Using FIG. 5A, a description will be given of the cumulative exchanged power amount information 33. The configuration of the cumulative exchanged power amount information 33 is similar to that of the contract information 32 (FIG. 4). The cumulative exchanged power amount information 33 is completed by: removing the transaction decision maker column 116, the transaction unit price column 117, the contract start time incentive name column 119, the contract end time incentive name column 120, and the shipment check column 121 from the contract information 32; and newly adding a cumulative exchanged power amount column (column 137 in FIG. 5A). The power exchange management device 1 obtains information indicative of amounts of power periodically supplied for exchange from the power management devices 52a, 52b of the prosumers (for example, twice every hour, on 0 and 30 minutes past every hour). Thus, for each of the power transaction entities 51a, 51b, the power exchange management device 1 calculates the total amount of power received/supplied since the contract start time, and periodically updates the cumulative amount of exchanged power which is stored in the cumulative exchanged power amount column 137.

### (Exchange Progress Graph)

Using FIG. 5B, a description will be given of an exchange progress graph 172. On the basis of the past history of each record in the cumulative exchanged power amount information 33, the power exchange management device 1 creates the exchange progress graph 172. The exchange progress graph 172 is a line graph which is drawn on a coordinate plane where the horizontal axis represents time points in the contract time period and the vertical axis represents the cumulative amount of exchanged power. The exchange progress graph 172 shows the cumulative amount of exchanged power at each time point. A target line 173 is a line joining the origin and a target point 174 whose coordinate values are “(contract end time, final total amount of power to be received/supplied)”. For each of the records shown in FIG. 5A, the power exchange management device 1 visualizes the record using the representation of the exchange progress graph 172. The exchange progress graph 172 shown in FIG. 5B is an example representing the time-series history of record 171 in FIG. 5A.

The contract time period between Oct. 10, 2016 and Dec. 31, 2016 has 12 weeks. With this taken into account, the power exchange management device 1 divides the target line 173 into 12 equal sections, and obtains a height 175 per section along the vertical axis. This height 175 represents a weekly average amount of power which Ms. Hitachi, Jane needs to supply in order for the target to be reached. If the exchange progress graph 172 is located under the target line 173, the power exchange management device 1 obtains a height difference 176 between the exchange progress graph 172 and the target line 173 at the current time point. This height difference 176 represents the amount of power which is required to be supplied at the current time in order for the target to be reached.

### (Process Procedure)

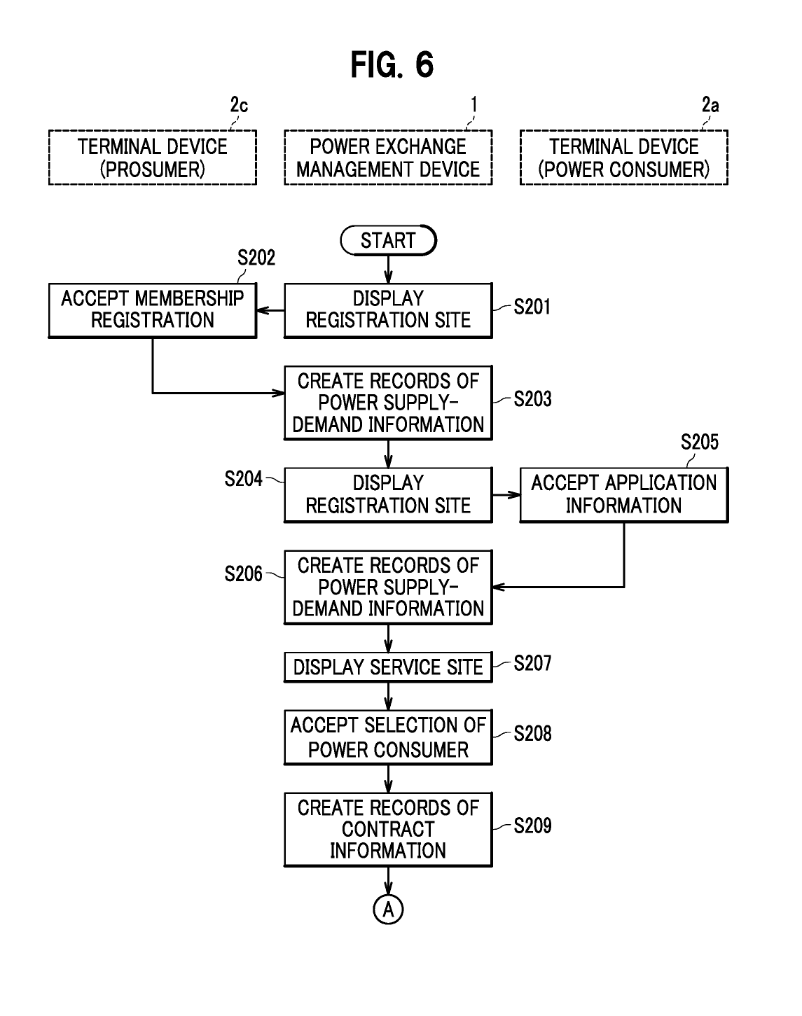

Using FIGS. 5A, 5B and 6, a description will be given of a process procedure. FIGS. 5A, 5B and 6 show the process procedure which the terminal device 2a of the prosumer, the terminal device 2c of the power consumer, and the power exchange management device 1 perform in cooperation. Incidentally, the terminal device 2a in FIGS. 5A, 5B and 6 is shown as a representative of the terminal devices 2a, 2b in FIG. 1. Similarly, the terminal device 2c in FIGS. 5A, 5B and 6 is shown as a representative of the terminal devices 2c, 2d in FIG. 1.

In step S201, the power consumer service processor 21 in the power exchange management device 1 displays a registration site. The registration site (not illustrated) is a portal site of the operator of the power exchange management device 1. Specifically, the power consumer service processor 21 displays a screen of the registration site on an output device of the terminal device 2c via the network 3. The registration site displays an invitation message like “You can receive power from prosumers in your local area by offering them local products”.

In step S202, the terminal device 2c accepts a membership registration. Specifically, first, the terminal device 2c receives information (bid solicitation information) about the following items (1) to (5), which is inputted by the power consumer using an input device of the terminal device 2c.

(1) the name and address of the power consumer

(2) a time period in which the power consumer can receive power (power exchange time period)

(3) multiple plans for amounts of power receivable from a prosumer in the power exchange time period (for example, a “100 kWh” plan, an “80 kWh” plan, . . . )

(4) incentives and values corresponding to the respective plans (referred to as “bid solicitation conditions”)

(5) desired transaction unit prices for the power transaction and each timing when the power consumer receives part of the power for exchange (although not essential)

Second, the terminal device 2c transmits the bid solicitation information to the power exchange management device 1. The power consumer service processor 21 in the power exchange management device 1 receives the bid solicitation information.

In step S203, the power consumer service processor 21 creates records of the power supply-demand information 31 (FIG. 3). Specifically, first, the power consumer service processor 21 creates as many new records as the plans of the power supply-demand information 31.

Second, the power consumer service processor 21 fills in the columns in each new record using the bid solicitation information. Examples of the records created in this step are the records 143 to 146 and 147 to 150 in FIG. 3.

In step S204, the prosumer service processor 22 in the power exchange management device 1 displays a registration site. Specifically, the prosumer service processor 22 displays a screen of the registration site on an output device of the terminal device 2a via the network 3. The registration site displays an invitation message like “You can receive local products by supplying power to a power consumer in your local area for exchange”.

In step S205, the terminal device 2a accepts application information. Specifically, first, the terminal device 2a receives application information about the following item (11), which is inputted by the prosumer using an input device of the terminal device 2a. Incidentally, if requested by the prosumer, the terminal device 2a receives application information about the following items (12) to (14). The reason why the input of the information about the items (12) to (14) is optional is that, in general, the prosumer as a private person rarely manages the information about the items (12) to (14) on a daily basis.

(11) the full name of the prosumer (which do not have to be the real names)

(12) the address of the prosumer, and the time period in which the prosumer can supply power (the power exchange time period)

(13) the amount of power which can be supplied at each time for exchange

(14) the desired transaction unit price for the power transaction, and each timing when the prosumer supplies the amount of power (although not essential)

Second, the terminal device 2a transmits the application information to the power exchange management device 1. The prosumer service processor 22 in the power exchange management device 1 receives the application information.

In step S206, the prosumer service processor 22 in the power exchange management device 1 creates a record of the power supply-demand information 31 (FIG. 3). Specifically, first, the prosumer service processor 22 creates a new record of the power supply-demand information 31.

Second, the prosumer service processor 22 fills in the columns in the new record using the application information. Examples of the record created in this step are the records 141, 142 in FIG. 3.

There is a case where the prosumer does not disclose the information about the items (12) to (14). In this case, the prosumer service processor 22 cannot fill in the columns surrounded by the thick line in the records 141, 142 in FIG. 3 only with the information received in the “second” part of step S205. Taking this into account, the prosumer service processor 22 stores past statistical values in the columns surrounded by the thick line. Examples of the past statistical values include: an amount of power obtained by daytime solar photovoltaic power generation in the corresponding area in the corresponding season (XX kWh per day per household); and an amount of power consumed by a power consuming facility (YY kWh per day per household). The prosumer service processor 22 may obtain such statistical values from an external server such as one belonging to a government agency or the like, or may estimate such statistical values on the basis of actual values (e.g., cumulative exchanged power amount information 33) of another prosumer.

The power consumer service processor 21 and the prosumer service processor 22 repeat the processes of steps S201 to S206 for many power consumers and many prosumers. As a result, many records are created as the power supply-demand information 31 like the one shown in FIG. 3.

In step S207, the prosumer service processor 22 displays a service site. Specifically, in response to a request from the prosumer, the prosumer service processor 22 displays a screen of the service site on the output device of the terminal device 2a via the network 3. The service site displays icons representing multiple power consumer candidates. It is preferable that each of the icons represents a product from the local area where the prosumer lives. The icons are linked to invitation messages like “You can receive an admission discount coupon equivalent to 1,000 yen in value by supplying 100 kWh to AA Dome in the time period from Jul. 1 to Dec. 31, 2016 for exchange. Alternatively, you can receive an idol T-shirt equivalent to 500 yen in value by supplying 80 kWh to AA Dome for exchange in the same period”.

The prosumer service processor 22 determines power consumer candidates which satisfy all or some of the conditions 1 to 4 described below, and displays (publicizes) selected power consumer candidates and the bid solicitation information including the bid solicitation conditions on the service site, to solicit for bids from the prosumer. In a case where multiple plans of a power consumer satisfy the conditions described below, the prosumer service processor 22 displays the multiple plans.

(Condition 1) The address of the power consumer is near the address of the prosumer (or the current position of the terminal device 2a of the prosumer), in such an extent that a predetermined standard is satisfied.

(Condition 2) At a time point in the future or during a time period in the future when the prosumer can supply power, the power consumer can receive the power. Specifically, in the power supply-demand information 31 in FIG. 3, part of the time period in which the prosumer can supply power for exchange overlaps part of the time period during which the power consumer can receive power for exchange. Incidentally, the prosumer service processor 22 may be configured to assign priorities to the power consumers in descending order of the overlapping period.

(Condition 3) In the power supply-demand information 31 in FIG. 3, a ratio of the amount of power which the prosumer can supply per each time (day) for exchange (column 105) to the total amount of power which the power consumer receives from a single prosumer in the power exchange time period (column 105) falls within a predetermined range. The predetermined range is expressed using an upper limit threshold and a lower limit threshold, for example, “10% or more but 20% or less”. If the ratio is less than the range, the prosumer may lose the motivation because the prosumer repeats the power exchange too many times and becomes tired in the middle of the contract time period. If the ratio is greater than the range, the prosumer may lose the motivation for accumulating small amounts of power on a one-by-one basis toward the target.

(Condition 4) The desired transaction unit price of the power consumer is greater than or equal to the desired transaction unit price of the prosumer. Incidentally, this condition is not essential.

In step S208, the prosumer service processor 22 accepts selection of a power consumer by the prosumer. Specifically, first, the prosumer service processor 22 allows the prosumer to select one of the multiple icons using the input device of the terminal device 2a.

Second, referring to the power supply-demand information 31, the prosumer service processor 22 retrieves the record concerning the power consumer associated with the selected icon. Thereafter, the prosumer service processor 22 displays information included in the retrieved record on the output device of the terminal device 2a in a freely selected format. It is preferable that the incentive name be linked to a page presenting a photograph and explanatory text that sufficiently represent the characteristics of the incentive.

Third, the prosumer service processor 22 allows the prosumer to activate a “Contract with this power consumer” button on the screen. In this part of step S208, the prosumer service processor 22 determines the prosumer who will supply power to the power consumer, meaning that a contract between the prosumer and the power consumer has been concluded. The prosumer service processor 22 displays a confirmation message like “You have contracted to supply power to AA Dome Corporation for exchange” on the output device of the terminal device 2a.

Fourth, referring to the power supply-demand information 31 (FIG. 3), the prosumer service processor 22 creates a scenario for exchange. Herein, assume that a contract is concluded between Ms. Hitachi, Jane (record 141 in FIG. 3) and AA Dome Corporation (record 144 in FIG. 3). In this case, the prosumer service processor 22 displays an exchange scenario that reads “Let us make a target of supplying 8 kWh/day 10 times by Dec. 31, 2016” on the output device of the terminal device 2a. In a case where, for example, the prosumer chooses “80 kWh” (record 144 in FIG. 3) as the target value of the contract, the prosumer service processor 22 proposes, for example, “8 kWh/day 10 times” in the exchange scenario, as mentioned above. The prosumer may change the schedule proposed in this proposal. In this case, taking into account the exchange capability of the prosumer, the prosumer changes the schedule such that the product of the amount of power to supply each time and the number of times of the supplies comes equal to the target value as specified in the contract. The prosumer service processor 22 receives a revised value “XX kWh/day YY times” and stores this value on the auxiliary storage 15 in association with the power consumer ID and the prosumer ID.

In step S209, the target manager 24 in the power exchange management device 1 creates a record of the contract information 32 (FIG. 4). Specifically, first, the target manager 24 creates a new record of the contract information 32.

Second, the target manager 24 fills the columns of the new record using the information described in the record of the prosumer and the information described in the record of the power consumer selected by the prosumer, which are both included in the power supply-demand information 31 (FIG. 3). An example of the record thus created is record 161 in FIG. 4. In this event, the contract end time incentive name column 120 and the shipment check column 121 in the created record are left blank. Step S209 in FIG. 5 continues to step S210 in FIG. 6.

In step S210, the target manager 24 determines whether the contract time period has started. Specifically, in a case where the contract start time (column 114 in FIG. 4) has been reached (“Yes” in step S210), the target manager 24 proceeds to step S211. In the other case (“No” in step S210), the target manager 24 waits for the time.

In step S211, the target manager 24 inquires about the amount of stored power. Specifically, the target manager 24 inquires of the terminal device 2a about the amount of stored power. The amount of stored power is the amount of power which is stored in the battery facility 55a of the prosumer at that time point and which can be supplied by the prosumer to the power consumer for exchange at that time point. As discussed above, the timing of step S210 can be determined in advance by the power consumer or the prosumer. In a case where neither the power consumer nor the prosumer determines the timing, the target manager 24 starts step S211 in a freely selected cycle (for example, at 9:00 a.m. everyday).

In step S212, the terminal device 2a transmits data on the amount of stored power. Specifically, the terminal device 2a accesses the power management device 52a, obtains data on the amount of power which is stored in the battery facility 55a at the time point, and transmits the data to the power exchange management device 1. The target manager 24 in the power exchange management device 1 receives the data on the amount of stored power.

In step S213, the target manager 24 in the power exchange management device 1 determines the amount of power to be supplied for exchange. For ease of understanding, explanation is continued with the assumption that the power consumer is AA Dome Corporation and the prosumer is Ms. Hitachi, Jane. The target manager 24 determines the amount of power to be supplied for exchange in this case in accordance with the following rules.

(Rule 1) If the amount of stored power represented by the data received in step S212 is less than a predetermined threshold (for example, in a case where the prosumer determines a minimum amount of stored power to be always stored for its own use, the minimum amount of stored power is used as the predetermined threshold), the target manager 24 sets a determined amount of power to be supplied for exchange at this time at “0 kWh”. Incidentally, Rule 1 is not essential (but optional).

(Rule 2) If the amount of stored power represented by the data received in step S212 is greater than or equal to the predetermined threshold, and if, in FIG. 5B, the cumulative amount of power exchanged by the current time point is less than the level represented by the target line 173, the target manager 24 sets the determined amount of power to be supplied for exchange at this time at the height difference 176 (amount of power which is required to be supplied at the current time point in order for the target to be reached). However, if the height difference 176 is greater than the amount of stored power represented by the data received in step S212, the target manager 24 sets the determined amount of power to be supplied for exchange at this time at the amount of stored power represented by the data received in step S212.

(Rule 3) If the amount of stored power as the data received in step S212 is equal to or greater than the predetermined threshold, and if, in FIG. 5B, the cumulative amount of power exchanged by the current time point is equal to or greater than the level represented by the target line 173, the target manager 24 sets the determined amount of power to be exchanged at this time at a predetermined amount of power (for example, an amount of power “8 kWh” in the record 141 in FIG. 3).

(Rule 4) In a case where the target manager 24 has accepted a notification from the terminal device 2a that the prosumer continues supplying the same amount of power, the target manager 24 sets the determined amount of power to be exchanged at this time at the height 175 in FIG. 5B (average amount of power which needs to be supplied in order for the target to be reached).

For ease of understanding, explanation is continued with the assumption that the determined amount of power to be supplied for exchange at this time is set at 8 kWh.

In step S214, the terminal device 2a supplies the power for exchange. Specifically, the terminal device 2a sends the power management device 52a of the prosumer an instruction instructing to “transmit 8 kWh out of the amount of power stored in the battery facility 55a to the battery facility 55c of AA Dome Corporation”. In step S215, the terminal device 2c stores power. Specifically, the terminal device 2c sends the power management device 52c of the power consumer an instruction instructing to “store 8 kWh transmitted from Ms. Hitachi, Jane in the battery facility 55c”.

In step S216, the terminal device 2c sends a power storing completion notice. Specifically, the terminal device 2c sends the power exchange management device 1 a notice that the storing of the power is completed (power storing completion notice). The power storing completion notice includes data on the amount of power which is actually received by and stored in the battery facility 55c as a result of the power transmission to the power grid 57 by reverse power flow (referred to as “amount of transmitted power”).

In step S217, the prosumer power transmission information acquirer 23 in the power exchange management device 1 receives the power storing completion notice from the terminal device 2c.

In step S218, the target manager 24 determines whether the contract time period ends. Specifically, in a case where the contract end time (column 115 in FIG. 4) of a contract has been reached (“Yes” in step S218), the target manager 24 proceeds to step S219. In the other case (if “No” in step S218), the target manager 24 returns to step S211.

The processes in step S210 to S218 are repeated for each of the prosumers registered in the contract information 32 (FIG. 4). Each time power is actually supplied for exchange, the target manager 24 updates the value of the cumulative amount of exchanged power in each record in the cumulative exchanged power amount information 33 (FIG. 5A) as the sum of the amounts of transmitted power. Each time the target manager 24 goes through step S217, the target manager 24 displays the updated cumulative amount of exchanged power on the terminal device 2a of the prosumer.

In step S219, the target manager 24 performs evaluation. The target manager 24 starts step S219 each time the contract end time of each contract has been reached. Herein, assume that the contract described in the record 161 of the contract information 32 (FIG. 4) ends (24:00 on Dec. 31, 2016 has been reached). When the contract ends, the target manager 24 performs evaluation for Ms. Hitachi, Jane (PS01). Specifically, the target manager 24 compares the cumulative amount of supplied power (actual value) W2 with the final total amount of power to be received/supplied (contracted value) W1 described in record 171 of the cumulative exchanged power amount information 33 (FIG. 5A). Depending on the result of the comparison, the target manager 24 determines an evaluation of the prosumer.

For example, if “W1≤W2”, the evaluation is determined as “excellent”. If “P≤W2<W1”, the evaluation is determined as “good”. If “W2<p”, the evaluation is determined as “positive”. In this respect, p is a number which satisfies 0<p<W1.

In step S220, the target manager 24 determines which incentive should be offered. Specifically, if the comprehensive evaluation of Ms. Hitachi, Jane is “excellent”, the target manager 24 determines the “idol T-shirt” (500 yen) as the incentive at the contract end time. Incidentally, a comprehensive evaluation of “good” corresponds to the “idol ballpoint pen” (200 yen), while a comprehensive evaluation of “positive” corresponds to the “idol patch” (100 yen). The incentive determined in this step can be different from the initially planned incentive. In this case, the target manager 24 displays the changed incentive to the terminal device 2a of the prosumer.

In step S221, the target manager 24 ships the incentive. Specifically, first, the target manager 24 transmits shipment information to a shipment server (not illustrated) of a delivery company. The shipment information includes: “idol T-shirt” as the incentive name; the address of a warehouse where incentives of AA Dome Corporation are stored; and the address of Ms. Hitachi, Jane. In this embodiment, the auxiliary storage 15 stores the addresses in association with the power transaction entity IDs. The delivery company receives the “idol T-shirt” at the warehouse, and delivers it to Ms. Hitachi, Jane.

Second, the target manager 24 creates a copy of record 161 included in the contract information 32 (FIG. 4), and stores it as record 165. Thereafter, the target manager 24 stores “idol T-shirt” in the contract end time incentive name column 120 of record 165, and stores a shipment flag “completed” in the shipment check column 121.

In step S222, the terminal device 2a receives the incentive. Specifically, the terminal device 2a of Ms. Hitachi, Jane reads a barcode or the like attached to the “idol T-shirt”, and acknowledges the reception. Thereafter, the process procedure is terminated.

(Bad Weather)

A power generation facility of a prosumer is not limited to a solar photovoltaic power generation facility. However, in a case where a prosumer has only a power generation facility which uses natural energy, the amount of power generated by the facility is subject to the weather condition. With this taken into account, the target manager 24 in the power exchange management device 1 performs the following measures when the final total amount of power to be received/supplied becomes less likely to be collected. In this respect, “when a final total amount of power to be received/supplied becomes less likely to be collected” is, for example, “when the cumulative amount of power exchanged by a time point becomes less than 50% of the level represented by the target line 173 at the time point in FIG. 5A”.

(Measure 1) The target manager 24 sends the terminal devices of the other contracted prosumers a message that reads “the power consumer is willing to increase the contracted final total amount of power to be received”.

(Measure 2) The target manager 24 sends the terminal devices of prosumer candidates, having not concluded a contract yet, a message for encouraging them to conclude a new contract. These candidates are prosumers who have been registered in the power supply-demand information 31 (FIG. 3) but have not been registered in the contract information 32 (FIG. 4).

(Screen Examples)

Examples of the screens to be displayed on the terminal device 2a of the prosumer by the power exchange management device 1 includes the following:

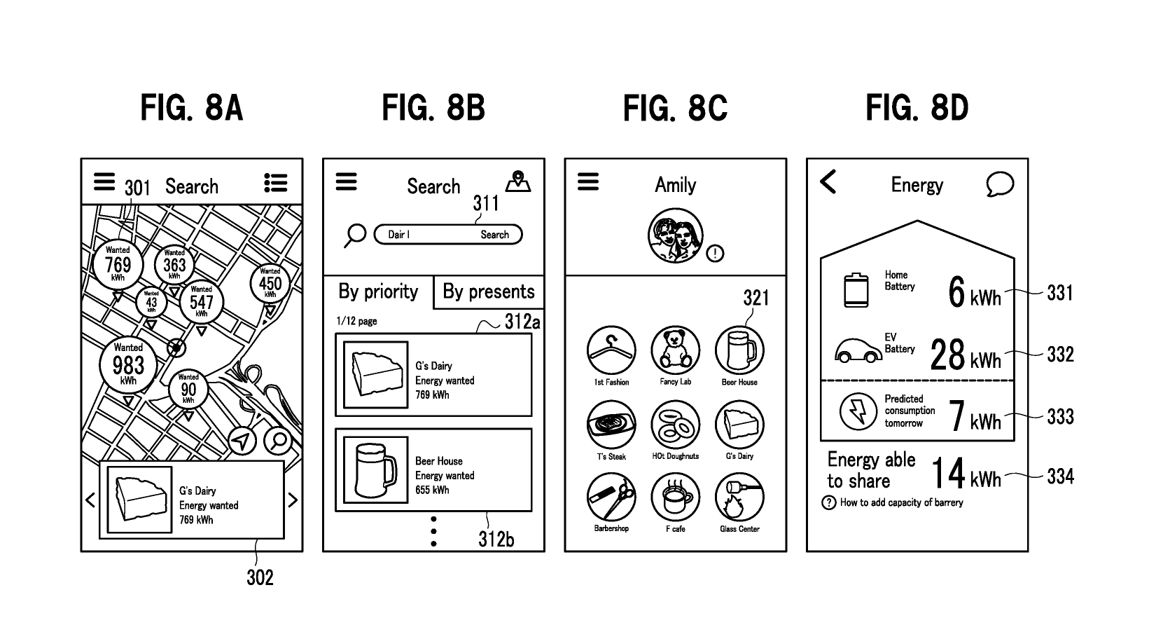

Power Consumer Selection Screen (FIG. 8A)

The prosumer service processor 22 displays a service site in step S207. FIG. 8A shows a power consumer selection screen of the service site that can be transitioned to. The prosumer service processor 22 displays a local map on the screen, and displays the locations of the power consumers included in the power supply-demand information 31 (FIG. 3) with circles 301 or the like. The amounts of power needed by the power consumers are displayed inside the respective circles. When the prosumer selects one of the circles, a photograph 302 of the incentive to be offered by the corresponding power consumer is displayed in a lower part of the screen.

Power Consumer Search Screen (FIG. 8B)

FIG. 8B shows a power consumer search screen of the service site that can also be transitioned to. The prosumer service processor 22 accepts a search keyword(s) inputted into a search box 311 by the prosumer. On the basis of the inputted search keyword(s), the prosumer service processor 22 searches the power supply-demand information 31 (FIG. 3), and displays icons or photographs 312a, 312b, . . . of the resulted power consumers by incentive categories (invent, food and the like). In FIG. 8B, “By presents” or the like is a tag representing a category.

Power Consumer Search Result Displaying Screen (FIG. 8C)

FIG. 8C shows a power consumer search result displaying screen of the service site that can also be transitioned to. The prosumer service processor 22 arranges and displays the icons or photographs 321 of many power consumers as a search result.

Exchangeable Power Amount Displaying Screen (FIG. 8D)

After the contract is concluded, the target manager 24 displays an exchangeable power amount displaying screen in FIG. 8D at a freely selected timing. The target manager 24 displays an amount of power stored by the prosumer at the current time point in a stored power amount column 331, an amount of power stored in a vehicle of the prosumer at the current time point (vehicle stored power amount) in a vehicle stored power amount column 332, and an amount of power predicted to be consumed on the following day in a predicted power consumption amount column 333.

The target manager 24 calculates an amount of exchangeable power using the following equation and displays the result of the calculation in an exchangeable power amount column 334:

amount of exchangeable power=amount of stored power+amount of power stored in vehicle−amount of power predicted to be consumed on the following day−predetermined safety margin

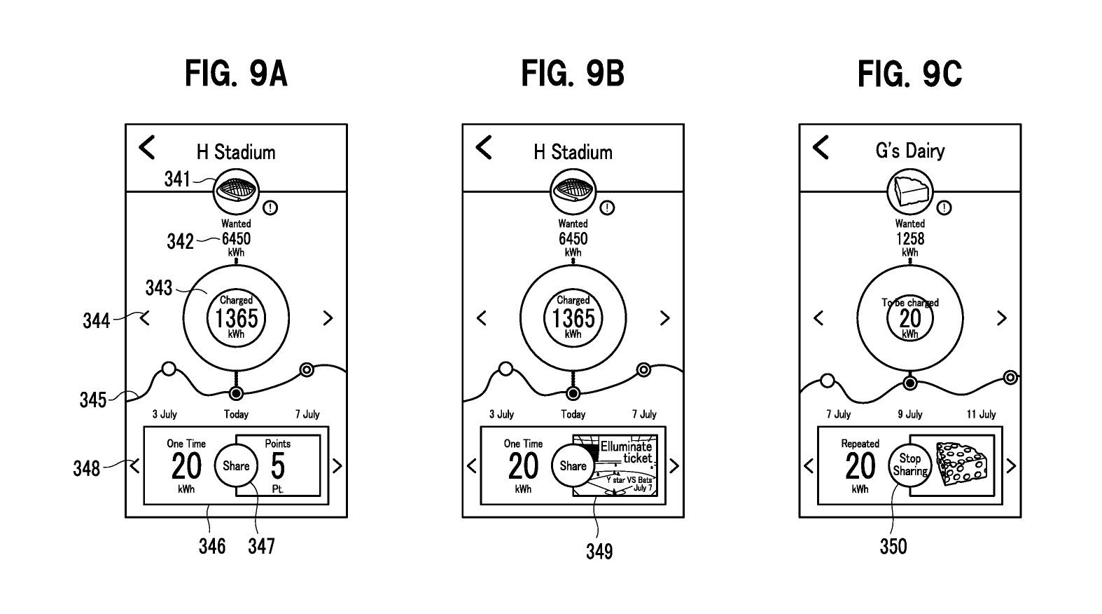

Power Exchange Screens (FIGS. 9A and 9B)

After the contract is concluded, the target manager 24 displays a power exchange screen as shown in FIG. 9A at a freely selected timing. The target manager 24 displays a photograph or icon 341 of a power consumer, an amount 342 of power needed by the power consumer at the current time point, an amount 343 of power stored by the power consumer at the current time point, and a graph 345 showing an actual amount of power stored by the power consumer in the past, or a predicted amount of power to be stored in the future. When a slider 344 is operated, the graph 345 moves leftward or rightward (the time point on the horizontal axis changes).

The target manager 24 displays an exchange determination column 346. The exchange determination column 346 displays “20 kWh” as the amount of power to be supplied from a prosumer at each time for exchange, and “5 points” as the value of an incentive which the prosumer will receive in a case where the prosumer supplies 20 kWh for exchange. When the exchange button 347 at the center of the exchange determination column 346 is pressed, the exchange is carried out. Incidentally, when the slider 348 is pressed, the value of the amount of power to be supplied for exchange and the incentive value increase or decrease.

When, in FIG. 9A, “5 points” in the exchange determination column 346 is pressed, an actual incentive having the value equivalent to the 5 points is displayed instead of “5 points”. In FIG. 9B, a photograph 349 of the actual incentive (invitation ticket of a night game) is displayed.

Exchange Suspension Screen (FIG. 9C)

As described above, after the target manager 24 periodically inquires of the prosumer about the amount of stored power, the actual exchange is carried out. In a case where the prosumer wishes to temporarily suspend such inquiries and supplying of power for exchange, the target manager 24 displays an exchange suspension screen in FIG. 9C. Once an exchange suspension button 350 in a lower part of the screen is pressed, the target manager 24 performs no inquiry from then.

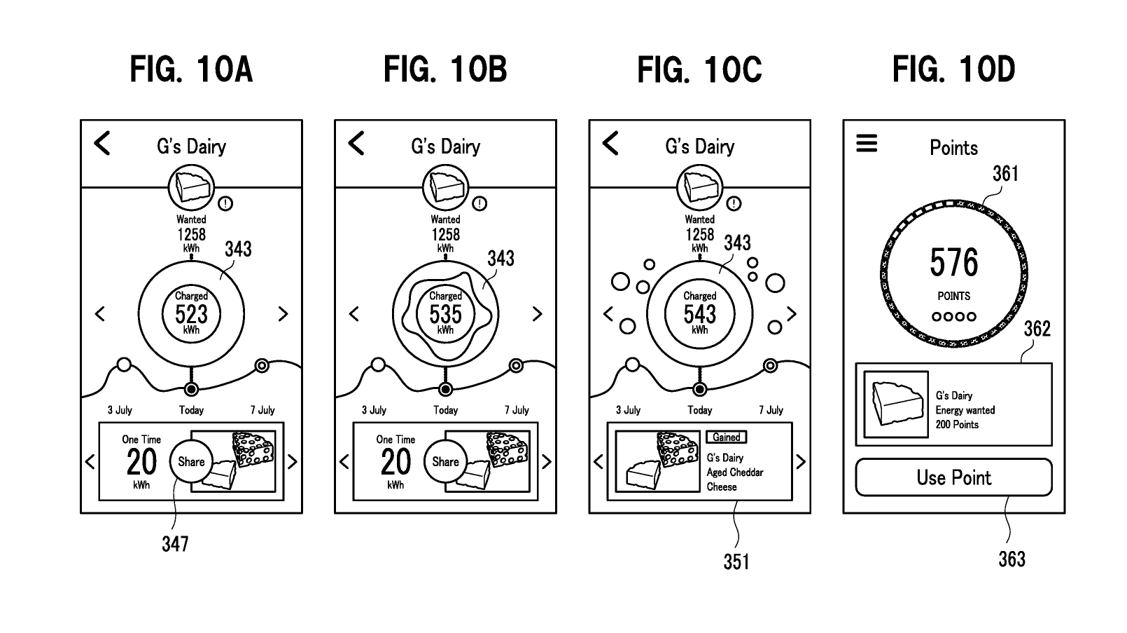

Exchange Confirmation Screens (FIGS. 10A, 10B and 10C)

An exchange confirmation screen shown in FIG. 10A is fundamentally the same as the screen in FIG. 9B. When the prosumer presses the exchange button 347, the graphical design representing the amount of stored power 343 dynamically changes (see FIG. 10B). At the next moment, the value of the amount 343 of stored power increases by “20 kWh” equivalent to the amount supplied for exchange. Thereafter, a photograph and an explanatory message 351 are displayed to indicate that the incentive has been obtained (see FIG. 10C).

Incentive Management Screen (FIG. 10D)

After the contract is concluded, the target manager 24 displays an incentive management screen shown in FIG. 10D at a freely selected timing. In the present embodiment, a virtual currency (points) used in the local area can be exchanged for an incentive depending on the value of the actual incentive. A point balance 361 in FIG. 10D is the number of points owned by the prosumer at the current time point. Upon receipt of a request from the prosumer, the target manager 24 displays a photograph 362 of a candidate incentive to be exchanged for points. When the prosumer selects the photograph 362 and presses a point exchange button 363, the target manager 24 subtracts points equivalent to the value of the incentive from the points left in the point balance 361, and displays a new point balance 361. Thereafter, the target manager 24 sends the shipment server an instruction instructing to ship the selected incentive to the prosumer.

### Advantageous Effects of Embodiment

Advantageous effects of the power exchange management device according to the embodiment are as follows.

(1) The power exchange management device is capable of keeping a prosumer motivated to supply power to a power consumer for exchange.

(2) The power exchange management device issues a solicitation for bids to prosumers capable of supplying power in a future time period. The power exchange management device is accordingly capable of keeping the prosumer motivated to supply an amount of power in the future.

(3) Each time a supply for exchange is carried out, the power exchange management device is capable of informing the prosumer of the amount of power which needs to be supplied at this time in order for a targeted total amount of exchanged power to be reached.

(4) The power exchange management device is capable of informing prosumers of power consumers which are prospective contract counterpart of the prosumers.

(5) When a contract is concluded, the power exchange management device is capable of informing the prosumer of the amount of power which the prosumer needs to supply at each time.

(6) The power exchange management device displays the value of a cumulative amount of supplied power. This makes it easy to keep the prosumer motivated.

(7) The power exchange management device displays multiple power consumer candidates to the prosumer. This makes the prosumer feel satisfaction when selecting a power consumer.

(8) The power exchange management device is capable of avoiding mistakenly shipping an incentive before power is actually exchanged.

(9) The power exchange management device allows the power consumer or the prosumer to determine timing at which to receive or supply power for exchange. This increases freedom of performing facility maintenance and the like.

The present invention is not limited to the foregoing embodiment, and includes various modifications. For example, the embodiment has been described in detail for the purpose of explaining the present invention in an easily understandable way, and the present invention is not necessarily limited to the embodiment which includes all the discussed components. Furthermore, some components included in one embodiment may be replaced with components included in another embodiment. In addition, components included in one embodiment may be added to the components included in another embodiment. Moreover, some components included in each embodiment may be added to the component included in another embodiment, may be removed, or may be replaced with components included in another embodiment.

Some of the foregoing components, functions, processors, processing means, and the like may be implemented using hardware, for example, by integrated circuit design and the like. In addition, the foregoing components, functions and the like may be implemented using software by causing a hardware processor to interpret and execute programs for implementing the functions. The programs for implementing the functions, as well as the information about the tables, files and the like may be stored in recorders such as a memory, a hard disk and a solid state drive (SSD), or on recording media such as an IC card, a SD card and a DVD.

Besides, control lines and information lines considered as being necessary for the explanation have been shown in the embodiment, but they are not necessarily all the control lines or all the information lines. Almost all the components may be considered as being actually connected together.

### REFERENCE SIGNS LIST

1 power exchange management device
2a, 2b, 2c, 2d terminal device
3 network
11 central control unit
12 input device
13 output device
14 main memory device
15 auxiliary storage
16 communication device
21 power consumer service processor
22 prosumer service processor
23 prosumer power transmission information acquirer
24 target manager
31 power supply-demand information
32 contract information
33 cumulative exchanged power amount information

1. A power exchange management device comprising:
a power consumer service processor that receives bid solicitation information from a terminal device of a power consumer, the bid solicitation information being for soliciting exchange of power, the power consumer having a battery facility capable of storing power from a grid, the power consumer using the power stored in the battery facility to produce products or provide services;
a prosumer service processor that publicizes a bid solicitation condition on a terminal device of a prosumer on the basis of the bid solicitation information and receives application information responding to the bid solicitation information from the terminal device of the prosumer, wherein the prosumer has (i) an in-house power generation facility and (ii) a power transmission facility capable of providing power to the grid by reverse power flow, and is thereby capable of transmitting power to the grid;
a prosumer power transmission information acquirer that acquires information about an amount of power transmitted to the grid by the power transmission facility of the prosumer by reverse power flow; and
a target manager that compares the acquired amount of transmitted power with a target value of an amount of power to be supplied from the prosumer to the power consumer and determines an incentive to be offered to the prosumer depending on a result of the comparison, wherein the target value is set on the basis of the bid solicitation information and the application information.

2. The power exchange management device according to claim 1,
wherein the bid solicitation information includes a future time period for reception of a supply of the power, an amount of power to be received for exchange, and information on the incentive, and
wherein the prosumer service processor issues a solicitation for bids to the prosumer by publicizing the future time period, the amount of power to be received for exchange, and the information on the incentive.

3. The power exchange management device according to claim 2,
wherein the target manager determines an amount of power to be supplied at a time point depending on a magnitude relationship between the target value of the amount of power to be supplied from the prosumer to the power consumer and a cumulative amount of power supplied by the time point.

4. The power exchange management device according to claim 3,
wherein the power consumer comprises a plurality of power consumers each having a terminal device, and
wherein the prosumer service processor determines one of the plurality of power consumers which can accept the exchange of the amount of power from the prosumer based on the bid solicitation information and the application information, and displays the determined one of the plurality of power consumers on the terminal device of the prosumer.

5. The power exchange management device according to claim 4,
wherein when a contract is concluded between the prosumer and the one of the plurality of power consumers, the prosumer service processor displays an amount of power to be supplied at every supply for exchange on the terminal device of the prosumer.

6. The power exchange management device according to claim 5,
wherein the target manager displays a cumulative value of the amount of transmitted power on the terminal device of the prosumer.

7. The power exchange management device according to claim 6,
wherein the prosumer service processor displays the plurality of power consumers on the terminal device of the prosumer as a plurality of candidates, and receives one candidate selected by the prosumer from the plurality of candidates.

8. The power exchange management device according to claim 7,
wherein after the target manager confirms that the amount of power is actually transmitted, the target manager outputs an instruction instructing to offer the incentive to the prosumer.

9. The power exchange management device according to claim 8,
wherein the power consumer service processor or the prosumer service processor receives information indicative of a timing at which to transmit power, from the prosumer or the one of the plurality of power consumers.

10. A power exchange management method for managing a power exchange management device, the power exchange management method comprising:
causing a power consumer service processor in the power exchange management device to receive bid solicitation information from a terminal device of a power consumer, the bid solicitation information being for soliciting exchange of power, the power consumer having a battery facility capable of storing power from a grid, the power consumer using the power stored in the battery facility to produce products or provide services;
causing a prosumer service processor in the power exchange management device to publicize a bid solicitation condition on a terminal device of a prosumer on the basis of the bid solicitation information and receive application information responding to the bid solicitation information from the terminal device of the prosumer, wherein the prosumer has (i) an in-house power generation facility and (ii) a power transmission facility capable of providing power to the grid by reverse power flow, and is thereby capable of transmitting power to the grid;
causing a prosumer power transmission information acquirer in the power exchange management device to acquire information about an amount of power transmitted to the grid by the power transmission facility of the prosumer by reverse power flow; and
causing a target manager in the power exchange management device to compare the acquired amount of transmitted power with a target value of an amount of power to be supplied from the prosumer to the power consumer and determine an incentive to be offered to the prosumer depending on a result of the comparison, wherein the target value is set on the basis of the bid solicitation information and the application information.

11. A non-transitory computer-readable medium storing a power exchange management computer program of causing a power exchange management device to function, the power exchange management computer program comprising sets of instructions for:
causing a power consumer service processor in a power exchange management device to perform a process of receiving bid solicitation information from a terminal device of a power consumer, the bid solicitation information being for soliciting exchange of power, the power consumer having a battery facility capable of storing power from a grid, the power consumer using the power stored in the battery facility to produce products or provide services;
causing a prosumer service processor in the power exchange management device to perform a process of publicizing a bid solicitation condition on a terminal device of a prosumer on the basis of the bid solicitation information and receiving application information responding to the bid solicitation information from the terminal device of the prosumer, wherein the prosumer has (i) an in-house power generation facility and (ii) a power transmission facility capable of providing power to the grid by reverse power flow, and is thereby capable of transmitting power to the grid;
causing a prosumer power transmission information acquirer in the power exchange management device to perform a process of acquiring information about an amount of power transmitted to the grid by the power transmission facility of the prosumer by reverse power flow; and
causing a target manager in the power exchange management device to perform a process of comparing the acquired amount of transmitted power with a target value of an amount of power to be supplied from the prosumer to the power consumer and determining an incentive to be offered to the prosumer depending on a result of the comparison, wherein the target value is set on the basis of the bid solicitation information and the application information.
